(19) United States
(12) Patent Application Publication
(10) Pub. No.: US 2013/0325374 A1
(43) Pub. Date: Dec. 5, 2013

(54) Method and System for the Preventive Maintenance of a Magnetic Resonance Device

(71) Applicant: Peter Häuser, Effeltrich (DE)

(72) Inventor: Peter Häuser, Effeltrich (DE)

(21) Appl. No.: 13/906,239

(22) Filed: May 30, 2013

(30) Foreign Application Priority Data
May 31, 2012 (DE) DE 102012209155.6

(51) Int. Cl. G01R 31/04

(52) U.S. Cl. CPC G01R 31/04
USPC 702/58

(57) ABSTRACT

A method and a system for preventive maintenance of a magnetic resonance device are provided. The system includes a coil plug-in connector detection unit that detects a number of coil connections of at least one high-frequency-receive coil of the magnetic resonance device. The system also includes a transmission unit that transmits the number of detected coil connections to a central arithmetic unit. The central arithmetic unit totals up the transmitted number of coil connections. The transmission unit also transmits the number of detected coil connections to an output unit. The transmission unit outputs a maintenance order for the maintenance of the magnetic resonance device when the total sum of the number of the coil connections exceeds a predefinable threshold value.

This application claims the benefit of DE 10 2012 209 155.6, filed on May 31, 2012, which is hereby incorporated by reference.

### FIELD

The embodiments relate to preventive maintenance of a magnetic resonance device.

### BACKGROUND

Magnetic resonance devices for the examination of objects or patients using magnetic resonance tomography are known, for example, from DE 10314215 B4. Modern magnetic resonance devices operate with high-frequency coils for the emission of high-frequency pulses for the nuclear resonance excitation of atoms and for the reception of induced magnetic resonance signals. A magnetic resonance device may have a large, whole body coil permanently built into the magnetic resonance device and a local coil arrangement with one or more (smaller) local coils.

In magnetic resonance tomography, images may be recorded with local coil arrangements. Atomic nuclei of an object under investigation excited by magnetic fields induce a voltage in at least one local coil. The induced voltage is amplified with a low-noise pre-amplifier and forwarded to a receive electronics unit using a cable connection.

The local coils (e.g., high-frequency receive coils) are anatomically shaped for the recording of patient images in order that the local coils may lie as closely as possible to the patient. For this reason, many differently shaped high-frequency receive coils having a form dependent on the region of the patient to be measured are used. On average, ten different high-frequency receive coils are employed.

For the measurement of magnetic resonance, the receive coils are to be connected to the magnetic resonance device via high-frequency plug-in connectors. As the signal received by the receive coils is very small, good high-frequency connections are used for signal transmission. As a result of the frequent withdrawal and plugging-in of the high-frequency plug-in connectors when changing the receive coils, wear is caused to the high-frequency contacts, which has a negative effect on the magnetic resonance image quality. Using an annual check on the high-frequency contacts, an attempt is made to detect mechanical wear at an early stage. In the case of a faulty connection, an error message is generated in the magnetic resonance device.

It may not be provided that an error message is always generated in the case of a faulty connection (e.g., with the high-frequency contacts). This is also the reason that wear of the contact surface is preventively reduced by a contact agent.

The published patent application DE 10 2010 048 329 A1 discloses a method and arrangement for detecting a number of plug cycles of a plug-in connection component (e.g., of a plug on a charging cable for an electric car). The number of plug cycles is, for example, totaled up in a central server. A warning signal is output upon the exceeding of a threshold value.

The published patent application DE 101 09 853 A1 discloses a method for the systematic evaluation of the quality of an operating medical engineering device of a type in which data captured during a regular check on the medical engineering device is transmitted to a central database and evaluated by an evaluation apparatus assigned to the database.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an automated method and a system for the preventive maintenance of a magnetic resonance device that prevent wear affecting high-frequency contacts of the receive coils are provided.

Automatic detection of the number of coil connections of the high-frequency receive coils in a magnetic resonance device is provided. If the number exceeds a threshold value, maintenance of the receive coils is undertaken.

In one embodiment, a method for the preventive maintenance of a magnetic resonance device with at least one coil plug-in connector detection unit is provided. A number of coil connections of at least one high-frequency-receive coil are detected by the coil plug-in connector detection unit. The detected number of coil connections is transmitted to a central arithmetic unit of a remote service center. The transmitted number of coil connections is totaled in the central arithmetic unit, and a maintenance order for maintenance of the magnetic resonance device is output when the sum of the number of coil connections has exceeded a predefinable threshold value. The threshold value is selected such that sufficient time for preventive maintenance of the high-frequency receive coils still remains. In at least some of the embodiments, the advantage that maintenance is only undertaken when required is provided, and unnecessary preventive maintenance activities are avoided.

In one embodiment, the maintenance order may include a checking and treatment of the high-frequency plug-in connectors of the at least one high-frequency receive coil.

The number of coil connections and totalizers of the number of coil connections may further be stored in a database of the central arithmetic unit.

In one embodiment of the method, the number of coil connections may be detected by the number of connections of high-frequency plug-in connectors of the high-frequency receive coils.

In one embodiment, a system for the preventive maintenance of a magnetic resonance device is provided. The system includes a coil plug-in connector detection unit that detects a number of coil connections of at least one high-frequency receive coil of magnetic resonance device. The system also includes a transmission unit that transmits the number of detected coil connections to a central arithmetic unit of a remote service center and an output unit. The central arithmetic unit totals up the transmitted number of coil connections, and the output unit issues a maintenance order for the maintenance of the magnetic resonance device when the total number of coil connections exceeds a predefinable threshold value. The threshold value is selected such that sufficient time remains for preventive maintenance of the high-frequency receive coils.

In one embodiment, the system may include a database in the central arithmetic unit, which stores the number of the coil connections and the total of the number of coil connections.

In a further embodiment, the system comprises high-frequency plug connectors of the receive coil, wherein the number of the coil connections is detected by means of the number of connections of the high-frequency plug connectors.

### BRIEF DESCRIPTION OF THE DRAWINGS

FIG. 1 shows a flowchart of one embodiment of a method for preventive maintenance of a magnetic resonance device; and

FIG. 2 shows a block diagram of one embodiment of a system with a coil plug-in connector detection unit in a magnetic resonance device.

### DETAILED DESCRIPTION

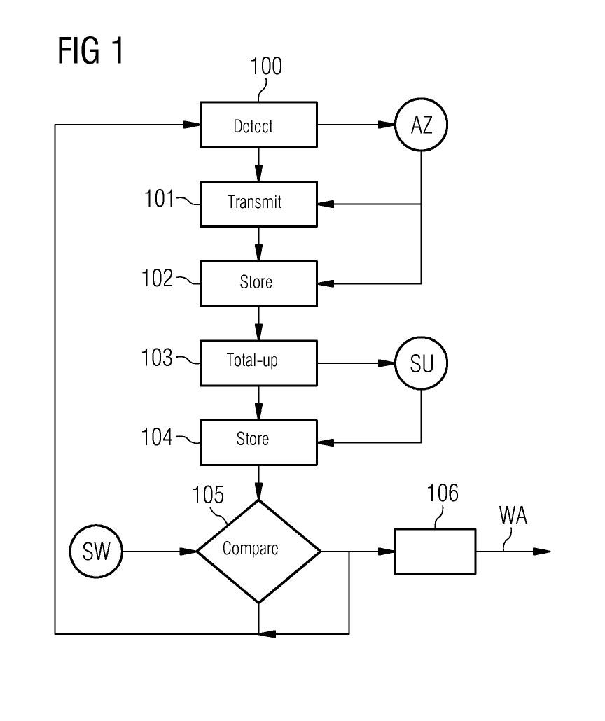

FIG. 1 shows a flowchart of one embodiment for the preventive maintenance of a magnetic resonance device. The magnetic resonance device includes a plurality of interchangeable high-frequency receive coils and a coil plug-in connector detection unit. In act 100, the number AZ of coil connections of the high-frequency receive coil is recorded (e.g., detected and counted by the coil plug-in connector detection unit). This may, for example, take place using detection sensors on the receive coils or alternatively using the detection of an interruption of an electrical connection. In act 101, the number AZ of coil connections is transmitted to a remote service center. This may take place upon each coil connection but also only at certain points in time. In act 102, the number AZ is stored in a database of the remote service center. In act 103, the number AZ of coil connections is totaled up in the remote service center, and in act 104, the total SU of the number AZ of coil connections is stored in the database.

In act 105, the remote service center checks whether the total SU has exceeded a predefinable, critical threshold value SW (SU>SW?). The threshold value SW is selected such that sufficient time still remains for preventive maintenance of the receive coils. If the threshold value SW has been exceeded, a maintenance order WA for maintenance of the magnetic resonance device is automatically output, and contact is established with the user of the device for the coordination of a maintenance date. At the same time, a service engineer is informed about the upcoming maintenance work.

By applying a suitable contact spray to the contacts of the plug-in connections of receive coils, unnecessary wear and poor signal quality may be counteracted.

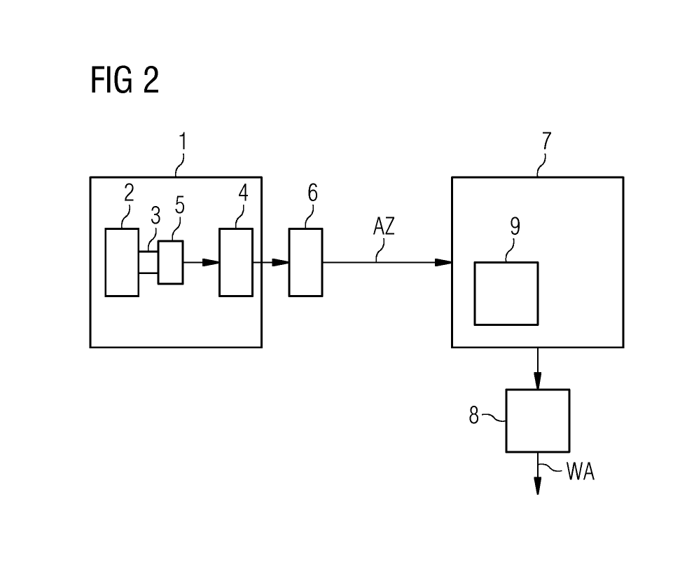

FIG. 2 shows a block diagram of one embodiment of a system with a magnetic resonance device 1. The magnetic resonance device 1 includes a plurality of high-frequency-receive coils 2 that are connected to the magnetic resonance device 1 with high-frequency plug connectors 3. Using the detection sensors 5, a coil plug-in connector detection unit 4 detects all connections of the receive coils 2.

There are no actual detection sensors for the coil connections in the system. The system has a coil recognition unit, and the coil has a unique coil ID, which is realized by a resistance matrix. How often a particular coil undergoes a plugging operation may thus be ascertained.

The number AZ of connections detected is transmitted to a central arithmetic unit 7 with the aid of a transmission unit 6 (e.g., to a remote service center). At the remote service center, the number AZ is stored in a database 9 and totaled up. When the total sum SU of the number AZ of the coil connections exceeds a predefinable threshold value SW, a maintenances order WA for the maintenance of the receive coils 3 of the magnetic resonance device 1 is output via an output unit 8 (e.g., a user service center).

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for preventive maintenance of a magnetic resonance device with at least one coil plug-in connector detection unit, the method comprising:
detecting a number of coil connections of at least one high-frequency receive coil by the coil plug-in connector detection unit;
transmitting the number of coil connections to a central arithmetic unit of a remote service center;
totaling-up of the transmitted number of coil connections in the central arithmetic unit; and
outputting a maintenance order for maintenance of the magnetic resonance device when a sum of the number of coil connections has exceeded a predefinable threshold value,
wherein the predefinable threshold value is selected such that time for a preventive maintenance of the at least one high-frequency-receive coil remains.

2. The method as claimed in claim 1, wherein the maintenance order comprises a checking and treatment of high-frequency plug connectors of the at least one high-frequency receive coil.

3. The method as claimed in claim 1, wherein the number of coil connections and the sum of the number of coil connections are stored in a database of the central arithmetic unit.

4. The method as claimed in claim 2, wherein detecting the number of the coil connections comprises detecting the number of the coil connections by a number of connections of the high-frequency plug connectors.

5. The method as claimed in claim 2, wherein the number of coil connections and the sum of the number of coil connections are stored in a database of the central arithmetic unit.

6. A system for preventive maintenance of a magnetic resonance device, the system comprising:
a coil plug-in connector detection unit operable to detect a number of coil connections of at least one high-frequency receive coil of the magnetic resonance device;
a transmission unit operable to transmit the number of the detected coil connections to a central arithmetic unit of a remote service center, the remote service center operable to total up the transmitted number of coil connections; and
an output unit operable to output a maintenance order for the maintenance of the magnetic resonance device when a total of the number of coil connections exceeds a predefinable threshold value,
wherein the predefinable threshold value is selected such that time for preventive maintenance of the high-frequency receive coils remains.

7. The system as claimed in claim 6, further comprising a high-frequency plug connector of the at least one high-frequency receive coil,
wherein the maintenance order comprises a checking and treatment of the high-frequency-plug connector.

8. The system as claimed in claim 6, further comprising a database of the central arithmetic unit,
wherein the database is configure to store the number of coil connections and a total sum of the number of coil connections.

9. The system as claimed in claim 7, wherein the coil plug-in connector detection unit is operable to detect the number of coil connections by a number of connections of the high-frequency plug connector.

10. The system as claimed in claim 7, further comprising a database of the central arithmetic unit,
wherein the database is operable to store the number of coil connections and a total sum of the number of coil connections.
